(19) United States
(12) Patent Application Publication
(10) Pub. No.: US 2026/0177332 A1
(43) Pub. Date: Jun. 25, 2026

(54) COOLING MODULE

(71) Applicant: NIDEC CORPORATION, Kyoto (JP)

(72) Inventors: Masahiro OTANI, Kyoto (JP); Takehito TAMAOKA, Kyoto (JP); Takaya OKUNO, Kyoto (JP); Tadahiro KURAMOTO, Kyoto (JP)

(21) Appl. No.: 19/419,586

(22) Filed: Dec. 15, 2025

Related U.S. Application Data
(60) Provisional application No. 63/736,670, filed on Dec. 20, 2024.

(30) Foreign Application Priority Data
Jul. 4, 2025 (JP) 2025-113737

(51) Int. Cl. F28F 9/02

(52) U.S. Cl. CPC F28F 9/0256

(57) ABSTRACT

A cooling module includes a manifold including a distribution manifold and a collection manifold. The distribution manifold includes a connection port of each of a plurality of joints connected to an inflow port of a refrigerant in a plurality of cooling units. The collection manifold includes a connection port of each of a plurality of joints connected to an outflow port of the refrigerant in the plurality of cooling units. The distribution manifold and the collection manifold are fixed to each other by a fixing portion.

### CROSS-REFERENCE TO RELATED APPLICATIONS

The present application is a Non-Provisional of U.S. Provisional Ser. No. 63/736,670 , filed on Dec. 20, 2024, and claims priority under 35 U.S.C. § 119 to Japanese Patent Application No. 2025-113737, filed on Jul. 4, 2025, the entire contents of which are hereby incorporated herein by reference.

### 1. Field of the Invention

The present disclosure relates to cooling modules.

### 2. BACKGROUND

There is a cooling module including a distribution manifold that distributes a refrigerant to a plurality of cooling units and a collection manifold that collects the refrigerant from the plurality of cooling units to which the refrigerant has been distributed.

When the cooling module of the related art is attached to an actual machine, the distribution manifold and the collection manifold need to be individually attached, and thus there is room for improvement in workability of attachment to the actual machine.

### SUMMARY

A cooling module according to an example embodiment of the present disclosure includes a manifold including a distribution manifold and a collection manifold. The distribution manifold includes a connection port of each of a plurality of joints connected to an inflow port of a refrigerant in a plurality of cooling units. The collection manifold includes a connection port of each of a plurality of joints connected to an outflow port of the refrigerant in the plurality of cooling units. The distribution manifold and the collection manifold are fixed to each other by a fixing portion.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an explanatory top view of a cooling module according to an example embodiment of the present disclosure.

FIG. 2 is an explanatory front view of a manifold according to an example embodiment of the present disclosure.

FIG. 3 is an explanatory top view of a connection portion of the distribution manifold according to an example embodiment of the present disclosure.

FIG. 4 is an explanatory top view of a connection portion in the collection manifold according to an example embodiment of the present disclosure.

FIG. 5 is an explanatory cross-sectional view of a manifold according to an example embodiment of the present disclosure.

FIG. 6 is an explanatory top view of a cooling module according to a first modification of an example embodiment of the present disclosure.

FIG. 7 is an explanatory top view of a distribution-side connection block according to the first modification.

FIG. 8 is an explanatory cross-sectional view of the distribution-side connection block according to the first modification.

FIG. 9 is an explanatory bottom view of a collection-side connection block according to the first modification.

FIG. 10 is an explanatory cross-sectional view of the collection-side connection block according to the first modification.

FIG. 11 is an explanatory top view of a connection portion between the collection manifold and the distribution-side connection block according to the first modification.

FIG. 12 is an explanatory top view of a connection portion between a collection-side connection block and a distribution manifold according to a second modification of an example embodiment of the present disclosure.

FIG. 13 is an explanatory cross-sectional view of the distribution-side connection block.

FIG. 14 is an explanatory cross-sectional view of the distribution-side connection block.

### DETAILED DESCRIPTION

Hereinafter, cooling modules according to example embodiments of the present disclosure will be described in detail with reference to the drawings. The present disclosure is not limited by the example embodiments. In the following example embodiments, components having the same function are denoted by the same reference numeral, and redundant description is omitted.

In the following example embodiments, expressions such as “constant”, “orthogonal”, “perpendicular”, and “parallel” may be used, but these expressions do not need to be strictly “constant”, “orthogonal”, “perpendicular”, and “parallel”. That is, each of the above-described expressions allows, for example, a deviation in manufacturing accuracy, installation accuracy, or the like.

In each of the drawings referred to below, in order to make the description easy to understand, an orthogonal coordinate system in which an X-axis direction, a Y-axis direction, and a Z-axis direction orthogonal or substantially orthogonal to each other are defined and a Z-axis positive direction is a vertically upward direction may be illustrated.

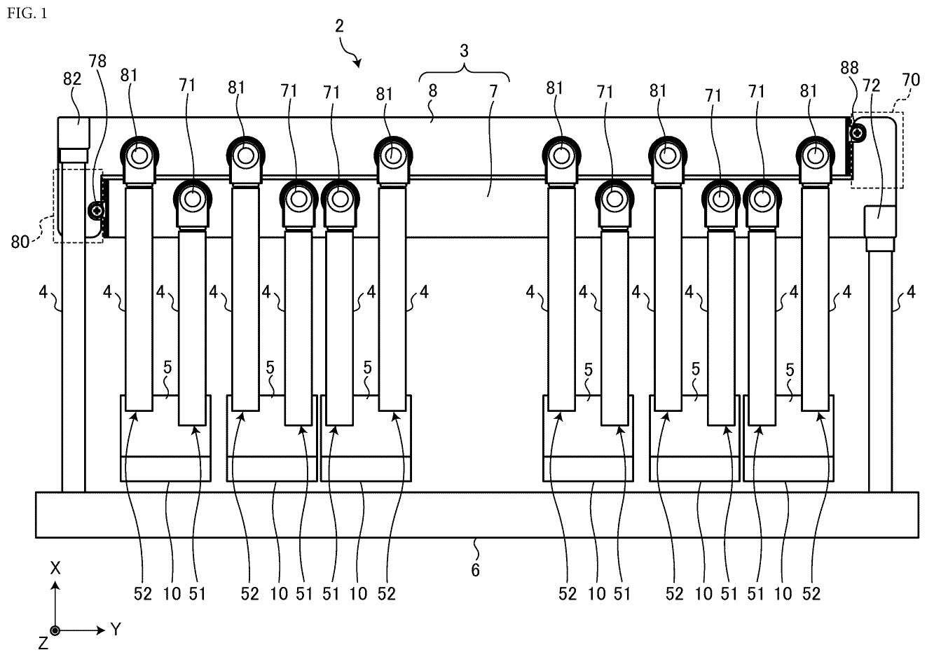

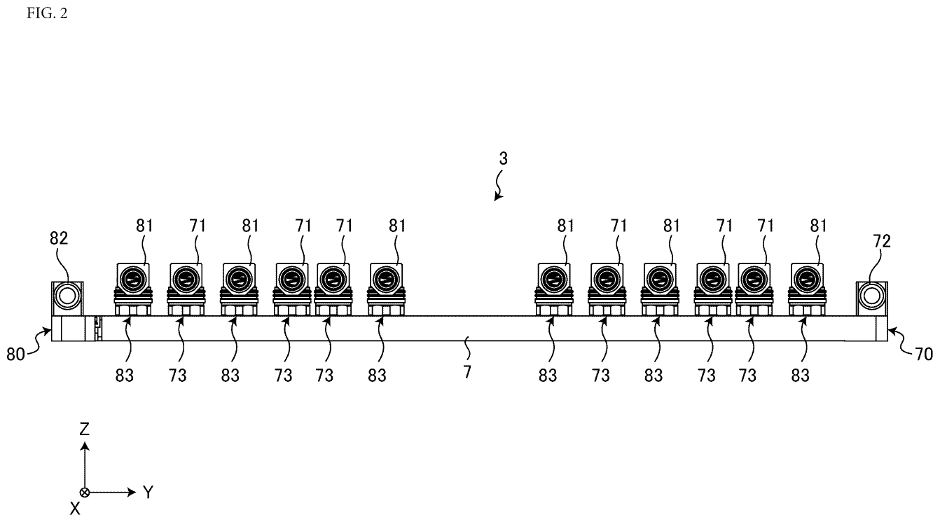

First, a configuration of a cooling module according to an exemplary example embodiment will be described with reference to FIGS. 1 and 2. FIG. 1 is an explanatory top view of a cooling module 2 according to an example embodiment. FIG. 2 is an explanatory front view of a manifold 3 according to the example embodiment. As illustrated in FIG. 1, the cooling module 2 includes the manifold 3, a plurality of flow path pipes 4, and a plurality of cooling units 5. The cooling module 2 is fluidly connected to an external flow path 6.

In one example, the external flow path 6 includes a refrigerant circulation device. The refrigerant circulation device is a device that cools the refrigerant flowing in from the cooling module 2 and sends the refrigerant to the cooling module 2 again. The refrigerant circulation device may include a radiator. The manifold 3 includes a distribution manifold 7 and a collection manifold 8. The distribution manifold 7 and the collection manifold 8 include an internal flow path through which the refrigerant flows.

The distribution manifold 7 includes a connection port of a plurality of joints (hereinafter, referred to as “distribution-side joints 71”) connected to an inflow port 51 of a refrigerant of the plurality of cooling units 5. The connection ports of the distribution-side joint 71 are arranged in a direction parallel to the first direction (Y-axis direction).

The distribution-side joint 71 is fluidly connected to the inflow port 51 of the refrigerant of the cooling unit 5 via the flow path pipe 4. The distribution manifold 7 includes, at an end portion on one side in the first direction (end portion on the positive side in the Y-axis direction), an inflow portion 72 into which the refrigerant flows from the external flow path 6 via the flow path pipe 4.

The collection manifold 8 includes a connection port of a plurality of joints (hereinafter, referred to as “collection-side joints 81”) connected to an outflow port 52 of the refrigerant in the plurality of cooling units 5. The connection ports of the collection-side joint 81 are arranged in a direction parallel to the first direction (Y-axis direction).

The collection-side joint 81 is fluidly connected to the refrigerant outflow port 52 of the cooling unit 5 via the flow path pipe 4. The collection manifold 8 includes, at an end portion on the other side in the first direction (end portion on the negative side in the Y-axis direction), an outflow portion 82 through which the refrigerant flows out to the external flow path 6 via the flow path pipe 4.

The cooling unit 5 is, for example, a cold plate. The cooling unit 5 is in thermal contact with a heat source 10. The heat source 10 is, for example, an arithmetic device such as a central processing unit (CPU). Each cooling unit 5 includes an internal flow path through which a refrigerant flows. The cooling unit 5 includes a plurality of fins that cause the refrigerant flowing through the internal flow path to absorb heat.

Here, the flow of the refrigerant in the cooling module 2 will be described. The cooled refrigerant sent from the external flow path 6 flows into the inflow portion 72 of the distribution manifold 7 via the flow path pipe 4. The refrigerant flowing into the distribution manifold 7 is distributed from each distribution-side joint 71 to each cooling unit 5 through the flow path pipe 4.

The refrigerant flowing into the inflow port 51 of each cooling unit 5 absorbs heat from the heat source 10 while passing through the internal flow path of the cooling unit 5, and flows into the collection manifold 8 from the outflow port 52 via the flow path pipe 4 and each collection-side joint 81.

The refrigerant that has flowed into the collection manifold 8 flows out from the outflow portion 82 and flows into the external flow path 6 via the flow path pipe 4. The refrigerant flowing into the external flow path 6 is cooled by, for example, a radiator in the process of passing through the external flow path 6, and is sent out to the distribution manifold 7 again.

In this way, the cooling module 2 can cool the heat source 10 by circulating the refrigerant through the external flow path 6, the distribution manifold 7, the cooling unit 5, the collection manifold 8, and the external flow path 6 in this order.

The distribution manifold 7 and the collection manifold 8 are fixed to each other by fixing portions 78, 88. As a result, the distribution manifold 7 and the collection manifold 8 can be attached to the actual machine at once, so that the workability of attachment to the actual machine is improved.

The distribution manifold 7 includes, at an end portion (end portion on the positive side in the Y-axis direction) on one side in the first direction at which the connection ports with the distribution-side joint 71 are aligned, a connection portion 70 that faces, in the first direction (Y-axis direction), an end portion (end portion on the positive side in the Y-axis direction) of the collection manifold 8 on one side in the first direction.

The collection manifold 8 includes, at the end portion on the other side in the first direction (the end portion on the negative side in the Y-axis direction) where the connection ports with the collection-side joint 81 are aligned, a connection portion 80 that faces, in the first direction (the Y-axis direction), the end portion of the distribution manifold 7 on the other side in the first direction (the end portion on the negative side in the Y-axis direction).

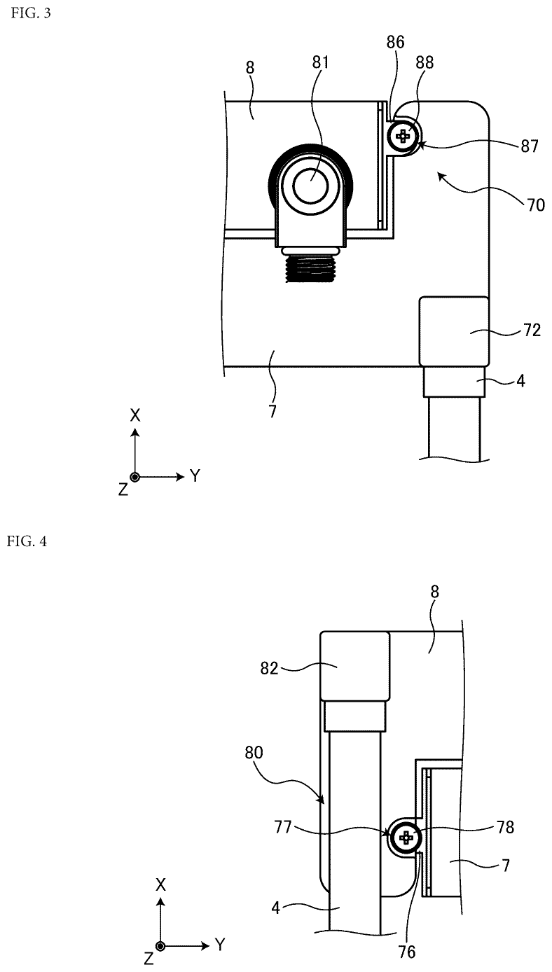

The distribution manifold 7 is fixed to the collection manifold 8 by the fixing portion 88 at the connection portion 70. The collection manifold 8 is fixed to the distribution manifold 7 by the fixing portion 78 at the connection portion 80. A specific configuration example of the connection portions 70, 80 will be described later with reference to FIGS. 3 and 4.

As described above, since the distribution manifold 7 and the collection manifold 8 are fixed to each other at both end portions in the first direction (Y-axis direction) that is the longitudinal direction, the fixing strength against vibration or the like is improved as compared with the case where the distribution manifold 7 and the collection manifold 8 are fixed at portions other than both end portions in the longitudinal direction. Therefore, the manifold 3 can suppress the occurrence of misalignment in the relative positions of the distribution manifold 7 and the collection manifold 8 after fixing.

As illustrated in FIG. 2, the distribution manifold 7 includes a connection port 73 connected to the distribution-side joint 71 on a surface (surface on the positive side in the Z-axis direction) on one side in the second direction orthogonal or substantially orthogonal to the first direction (Y-axis direction). Similarly, the collection manifold 8 includes a connection port 83 with the collection-side joint 81 on a surface on one side in the second direction (surface on the positive side in the Z-axis direction).

The connection port 73 of the distribution manifold 7 and the connection port 83 of the collection manifold 8 are disposed at positions that do not overlap in the third direction (X-axis direction) orthogonal or substantially orthogonal to the first direction (Y-axis direction) and the second direction (Z-axis direction).

As a result, all of the flow path pipes 4 connecting the respective connection ports 73, 83 and the cooling unit 5 can be collectively disposed on the same side in the third direction (the negative side in the X-axis direction in FIGS. 1 and 2), so that the flow path pipes 4 can be easily handled. Further, the work of fixing each of the distribution manifold 7 and the collection manifold 8 to each other by the fixing portions 78, 88 is facilitated.

As illustrated in FIG. 1, the distribution manifold 7 and the collection manifold 8 are fixed to each other with a space therebetween. Specifically, the distribution manifold 7 and the collection manifold 8 are fixed at an interval in the first direction (Y-axis direction) and the third direction (X-axis direction). In other words, the collection manifold 8 and the distribution manifold 7 are disposed so as not to be in contact with each other except for the portions fixed to each other.

As a result, the manifold 3 can suppress the transfer of heat from the collection manifold 8, through which the refrigerant that has absorbed heat from the heat source 10 in the cooling unit 5 flows, to the distribution manifold 7, through which the refrigerant that has been cooled in the external flow path 6 flows, and thus can prevent a decrease in the cooling performance of the cooling module 2.

Further, in the manifold 3, the heat transfer can be suppressed by setting the interval between the collection manifold 8 and the distribution manifold 7 to, for example, 0.1 mm or more. In the present example embodiment, the interval is about 2 mm wide.

Although not illustrated in FIG. 1, the heat insulation performance of the manifold 3 can be further improved by inserting a material having a high heat insulation property between the collection manifold 8 and the distribution manifold 7.

The collection manifold 8 and the distribution manifold 7 are also spaced apart from each other in the first direction (Y-axis direction). Therefore, when attached to the actual machine (for example, the heat source 10), the collection manifold 8 and the distribution manifold 7 can be disposed to be shifted in the first direction (Y-axis direction), so that the attachability is improved. In addition, the distribution manifold 7 and the collection manifold 8 can be easily fixed to and removed from each other, and it becomes easy to perform adjustment of the position at the time of attachment to the actual machine.

In addition, the greater the spacing, the greater the width over which the collection manifold 8 and the distribution manifold 7 can be offset, thereby further improving mountability and also improving the ability to inhibit the undesirable heat transfer described above.

In addition, since the surfaces of the collection manifold 8 and the distribution manifold 7 that do not face each other are flat surfaces, it is possible to suppress interference with other members when attached to an actual machine (for example, the heat source 10).

Next, the connection portion 70 of the distribution manifold 7 and the connection portion 80 of the collection manifold 8 will be described with reference to FIGS. 3 and 4. FIG. 3 is an explanatory top view of the connection portion 70 in the distribution manifold 7 according to the example embodiment. FIG. 4 is an explanatory top view of the connection portion 80 in the collection manifold 8 according to the example embodiment.

As illustrated in FIG. 3, the collection manifold 8 includes a flange 86. The flange 86 extends from the end portion of the collection manifold 8 on one side in the first direction (the end portion on the positive side in the Y-axis direction) to a position overlapping the connection portion 70 of the distribution manifold 7 in the second direction (the Z-axis direction) orthogonal or substantially orthogonal to the first direction.

The collection manifold 8 is fixed to the distribution manifold 7 by the fixing portion 88 inserted into the hole portion 87 of the flange 86 from one side in the second direction (the positive side in the Z-axis direction). The fixing portion 88 is, for example, a screw.

As illustrated in FIG. 4, the distribution manifold 7 includes a flange 76. The flange 76 extends from an end portion of the distribution manifold 7 on the other side in the first direction (end portion on the negative side in the Y-axis direction) to a position overlapping the connection portion 80 of the collection manifold 8 in the second direction (Z-axis direction) orthogonal or substantially orthogonal to the first direction.

The distribution manifold 7 is fixed to the collection manifold 8 by the fixing portion 78 inserted into the hole portion 77 of the flange 76 from one side in the second direction (the positive side in the Z-axis direction). The fixing portion 78 is, for example, a screw.

As a result, the manifold 3 can suppress the occurrence of misalignment between the distribution manifold 7 and the collection manifold 8 due to vibration or the like. Furthermore, the distribution manifold 7 and the collection manifold 8 can be easily fixed to and removed from each other, and it becomes easy to perform adjustment of the position at the time of attachment to the actual machine. In addition, since the fixing portions 78, 88 are both inserted into the manifold 3 from one side in the second direction (the positive side in the Z-axis direction), the fixing work of the distribution manifold 7 and the collection manifold 8 is facilitated.

The flange 86 of the collection manifold 8 may be disposed on one side in the second direction (the positive side in the Z-axis direction) of the connection portion 70 of the distribution manifold 7, and the flange 76 of the distribution manifold 7 may be disposed on the other side in the second direction (the negative side in the Z-axis direction) of the connection portion 80 of the collection manifold 8. The flange 86 of the collection manifold 8 may be disposed on the other side in the second direction (the negative side in the Z-axis direction) of the connection portion 70 of the distribution manifold 7, and the flange 76 of the distribution manifold 7 may be disposed on one side in the second direction (the positive side in the Z-axis direction) of the connection portion 80 of the collection manifold 8.

As a result, even in a state where the distribution manifold 7 and the collection manifold 8 are not fixed by the fixing portions 78, 88, the distribution manifold 7 and the collection manifold 8 are not easily separated from each other. Therefore, workability at the time of the fixing work and the redoing work of the fixing by the fixing portions 78, 88 is improved.

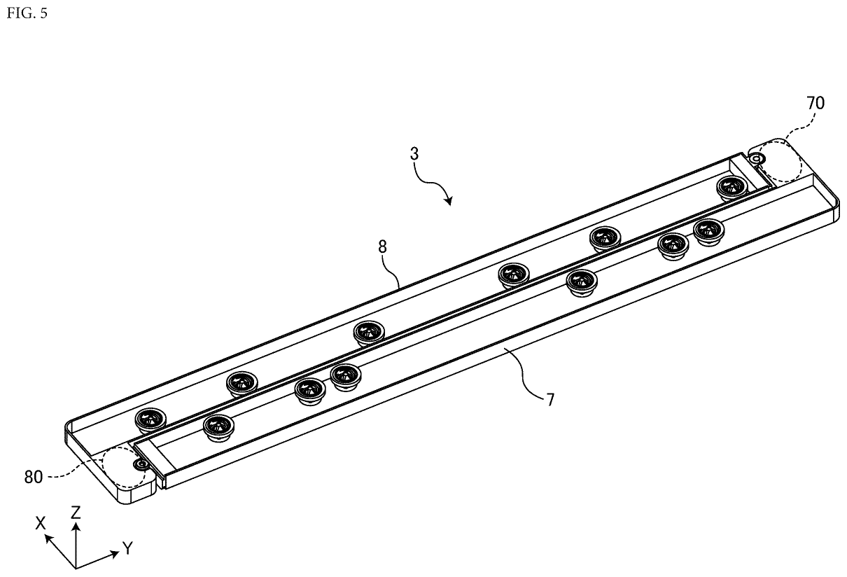

Next, the internal structure of the manifold 3 will be described with reference to FIG. 5. FIG. 5 is an explanatory cross-sectional view of the manifold 3 according to the example embodiment. As illustrated in FIG. 5, the inside of the distribution manifold 7 at a position where the inflow portion 72 (see FIG. 1) of the refrigerant is provided communicates with the internal flow path of the distribution manifold 7, but the inside of the connection portion 70 where the inflow portion 72 is not provided is filled.

As a result, the transfer of heat from the collection manifold 8, in which the refrigerant that has absorbed heat from the heat source 10 flows, to the refrigerant flowing inside the distribution manifold 7 via the connection portion 70 of the distribution manifold 7 can be suppressed.

In the collection manifold 8, the inside of the position where the outflow portion 82 (see FIG. 1) of the refrigerant is provided communicates with the internal flow path of the collection manifold 8, but the inside of the connection portion 80 where the outflow portion 82 is not provided is filled.

As a result, it is possible to suppress the transfer of heat from the collection manifold 8 in which the refrigerant that has absorbed heat from the heat source 10 flows to the refrigerant flowing inside the distribution manifold 7 via the connection portion 80 in which the outflow portion 82 is not provided.

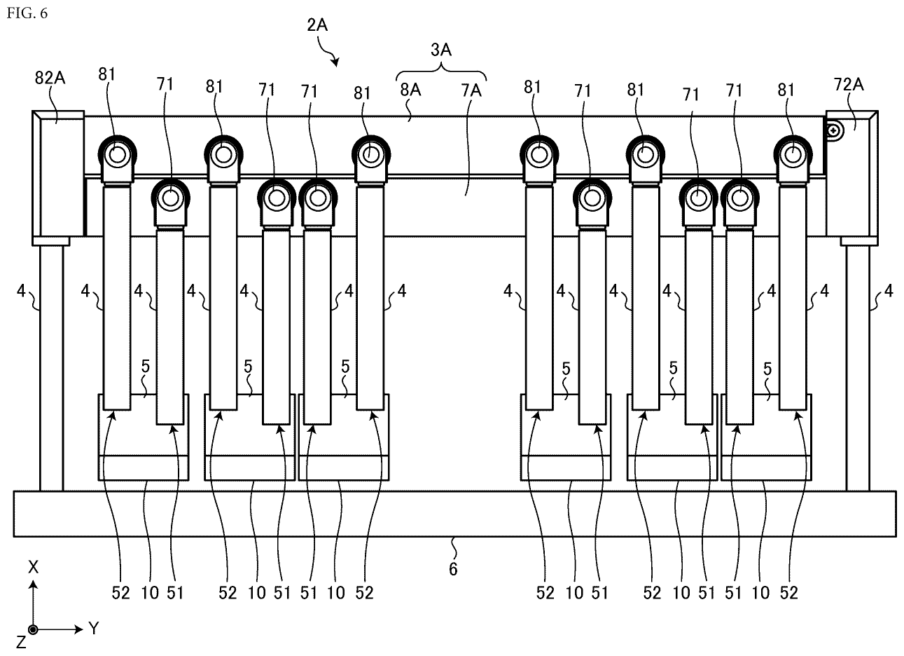

Next, a cooling module 2A according to a first modification of the example embodiment will be described with reference to FIG. 6. FIG. 6 is an explanatory top view of the cooling module 2A according to a first modification of the example embodiment. As illustrated in FIG. 6, the configuration of a manifold 3A of the cooling module 2A differs from the configuration of the manifold 3 illustrated in FIG. 1. To be more specific, a distribution manifold 7A of the manifold 3A includes a distribution-side connection block 72A instead of the connection portion 70 and the inflow portion 72 illustrated in FIG. 1. A collection manifold 8A of the manifold 3A includes a collection-side connection block 82A instead of the outflow portion 82 and the connection portion 80 illustrated in FIG. 1.

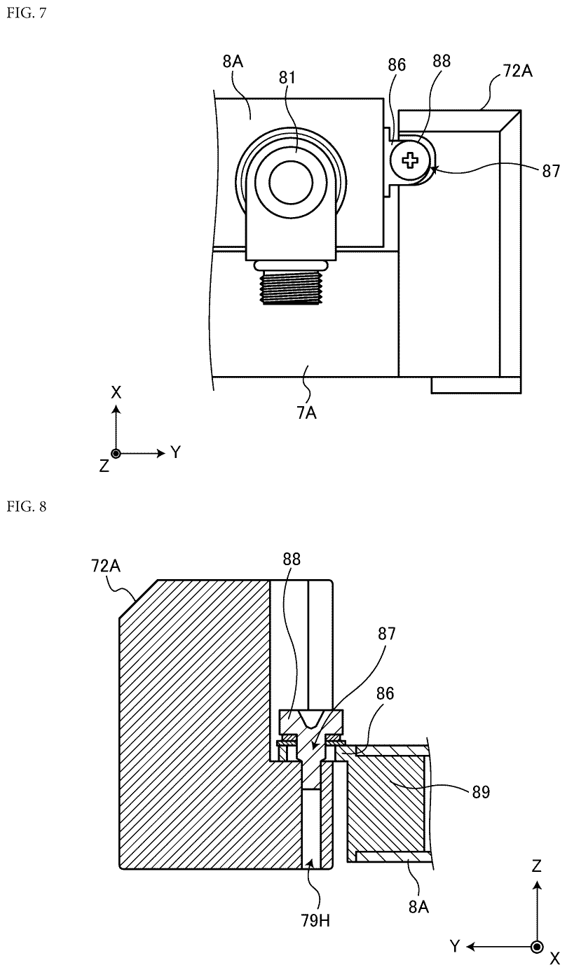

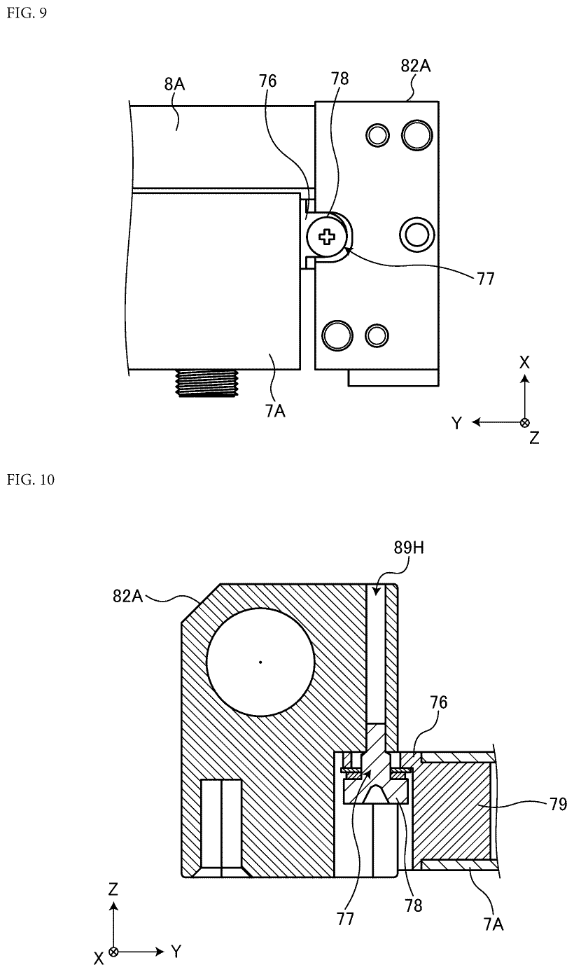

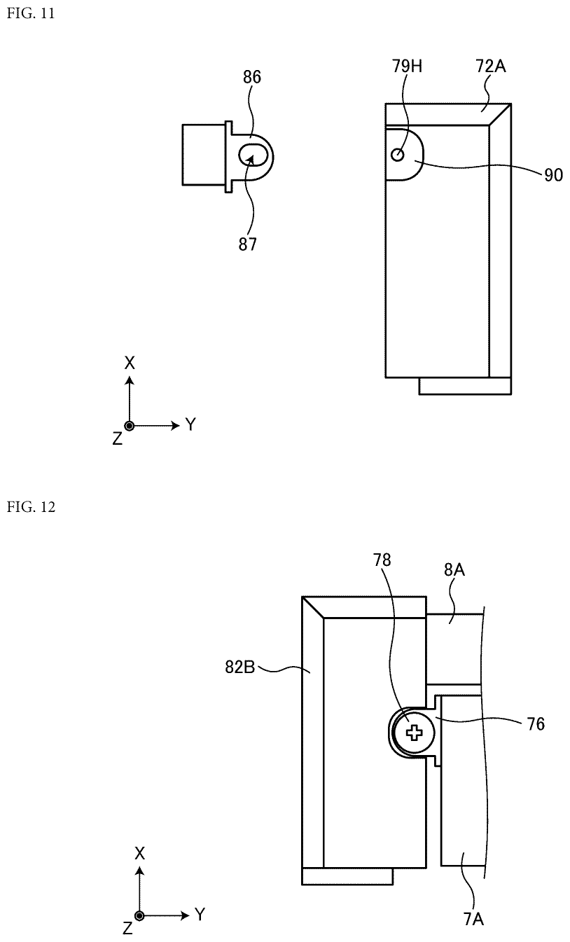

Next, the distribution-side connection block 72A and the collection-side connection block 82A according to the example embodiment will be described with reference to FIGS. 7 to 12. FIG. 7 is an explanatory top view of the distribution-side connection block 72A according to a modification. FIG. 8 is an explanatory cross-sectional view of the distribution-side connection block 72A according to the modification. FIG. 9 is an explanatory bottom view of the collection-side connection block 82A according to the modification. FIG. 10 is an explanatory cross-sectional view of the collection-side connection block 82A according to the modification. FIG. 11 is an explanatory top view of the connection portion between the collection manifold 8 and the distribution-side connection block 72A according to the modification. FIG. 12 is an explanatory top view of a connection portion between the collection-side connection block 82A and the distribution manifold 7 according to the modification.

As illustrated in FIGS. 7 and 8, the distribution manifold 7A includes, at an end portion on one side in the first direction (end portion on the positive side in the Y-axis direction), the distribution-side connection block 72A into which the refrigerant flows from the external flow path 6. As illustrated in FIGS. 9 and 10, the collection manifold 8A includes, at the end portion on the other side in the first direction (the end portion on the negative side in the Y-axis direction), the collection-side connection block 82A that allows the refrigerant to flow out from the collection manifold 8A to the external flow path 6.

At least a portion of the distribution-side connection block 72A is fixed to an end portion of the collection manifold 8A on one side in the first direction (an end portion on the positive side in the Y-axis direction). At least a part of the collection-side connection block 82A is fixed to the end portion of the distribution manifold 7 on the other side in the first direction (the end portion on the negative side in the Y-axis direction).

This facilitates fixing of the distribution-side connection block 72A to the collection manifold 8A and fixing of the collection-side connection block 82A to the distribution manifold 7A. Further, misalignment between the distribution-side connection block 72A and the collection manifold 8A and misalignment between the collection-side connection block 82A and the distribution manifold 7A due to vibration or the like can be suppressed.

As illustrated in FIGS. 7 and 8, the collection manifold 8A includes a flange 86 extending from the end portion on one side in the first direction (the end portion on the positive side in the Y-axis direction) to a position overlapping the distribution-side connection block 72A in the second direction (the Z-axis direction). The flange 86 of the collection manifold 8A is fastened to the distribution-side connection block 72A by the fixing portion 88 inserted into the hole portion 87 of the flange 86 from one side in the second direction (the positive side in the Z-axis direction). The fixing portion 88 is, for example, a screw.

The flange 86 of the collection manifold 8A extends from the end surface on one side in the first direction (the end surface on the positive side in the Y-axis direction) of a wall portion 89 that seals the end surface on one side in the first direction (the end surface on the positive side in the Y-axis direction) of the collection manifold 8A. The flange 86 extends from a position flush with the end surface of the collection manifold 8A on one side in the second direction (the end surface on the positive side in the Z-axis direction) to a position overlapping the distribution-side connection block 72A in the second direction (the Z-axis direction).

The flange 86 and the distribution-side connection block 72A include hole portions 87, 79H at positions overlapping in the second direction (Z-axis direction), and the distribution-side connection block 72A and the collection manifold 8A can be fixed by the fixing portion 88.

Thus, it is possible to suppress the occurrence of misalignment between the distribution-side connection block 72A and the collection manifold 8A due to vibration or the like. Furthermore, the distribution-side connection block 72A and the collection manifold 8A can be easily fixed to and removed from each other, and it becomes easy to perform adjustment of the position at the time of attachment to the actual machine (for example, the heat source 10).

As illustrated in FIGS. 9 and 10, the distribution manifold 7A includes the flange 76 extending from the end potion on the other side in the first direction (the end portion on the negative side in the Y-axis direction) to a position overlapping the collection-side connection block 82A in the second direction (the Z-axis direction). The flange 76 of the distribution manifold 7A is fastened to the collection-side connection block 82A by the fixing portion 78 inserted into the hole portion 77 of the flange 76 from the other side in the second direction (the negative side in the Z-axis direction). The fixing portion 78 is, for example, a screw.

The flange 76 of the distribution manifold 7A extends from the end surface on the other side in the first direction (the end surface on the negative side in the Y-axis direction) of a wall portion 79 that seals the end surface on the other side in the first direction (the end surface on the negative side in the Y-axis direction) of the distribution manifold 7A. The flange 76 extends from a position flush with the end surface of the distribution manifold 7A on one side in the second direction (the end surface on the positive side in the Z-axis direction) to a position overlapping the collection-side connection block 82A in the second direction (the Z-axis direction).

The flange 76 and the collection-side connection block 82A include hole portions 77, 89H at positions overlapping in the second direction (Z-axis direction), and the collection-side connection block 82A and the distribution manifold 7A can be fixed by the fixing portion 78.

Accordingly, it is possible to suppress occurrence of positional deviation between the collection-side connection block 82A and the distribution manifold 7A due to vibration or the like. Further, the collection-side connection block 82A and the distribution manifold 7A can be easily fixed to and removed from each other, and it becomes easy to perform adjustment of the position at the time of attachment to the actual machine (for example, the heat source 10).

The collection manifold 8A and the wall portion 89 can be formed of metals. Also, the distribution manifold 7A and the wall portion 79 can be formed of metals. The collection manifold 8A and the wall portion 89 can be welded by brazing, laser welding, or the like. Similarly, the distribution manifold 7A and the wall portion 79 can be welded by brazing, laser welding, or the like. Accordingly, it is possible to reliably suppress liquid leakage with high sealing accuracy.

The height of the flange 86 of the collection manifold 8A can be varied to accommodate the shape of the distribution-side connection block 72A. The height of the flange 76 of the distribution manifold 7A can be varied to accommodate the shape of the collection-side connection block 82A.

The wall portion 89 of the collection manifold 8A and the distribution-side connection block 72A face each other with a space therebetween. Therefore, heat transfer between the collection manifold 8A and the distribution-side connection block 72A can be suppressed. Similarly, the wall portion 79 of the distribution manifold 7A and the collection-side connection block 82A face each other with a space therebetween. Therefore, heat transfer between the distribution manifold 7A and the collection-side connection block 82A can be suppressed.

As illustrated in FIGS. 9 and 10, the flange 76 of the distribution manifold 7 is disposed on the other side in the second direction (the negative side in the Z-axis direction) of the collection-side connection block 82A. On the other hand, as illustrated in FIGS. 7 and 8, the flange 86 of the collection manifold 8 is disposed on one side in the second direction (positive side in the Z-axis direction) of the distribution-side connection block 72A.

When the fixing portion 78 is a screw, the distribution manifold 7A is screwed to the collection-side connection block 82A by the fixing portion 78 from the other side in the second direction (the negative side in the Z-axis direction). When the fixing portion 88 is a screw, the collection manifold 8A is screwed to the distribution-side connection block 72A by the fixing portion 88 from one side in the second direction (the positive side in the Z-axis direction). This makes it easy to combine the distribution manifold 7A and the collection manifold 8A while avoiding the connection parts of the distribution-side joint 71 and the collection-side joint 81. As a result, even in a state where the distribution manifold 7 and the collection manifold 8 are not fixed by the fixing portions 78, 88, the distribution manifold 7 and the collection manifold 8 are not easily separated from each other. Therefore, workability at the time of the fixing work and the redoing work of the fixing by the fixing portions 78, 88 is improved.

As illustrated in FIG. 11, the hole portion 87 of the flange 86 of the collection manifold 8A has larger widths in the first direction (Y-axis direction) and the third direction (X-axis direction) than the hole portion 79H provided in the distribution-side connection block 72A. Similarly, the hole portion 77 of the flange 76 of the distribution manifold 7A has larger widths in the first direction (Y-axis direction) and the third direction (X-axis direction) than the hole portion 89H provided in the collection-side connection block 82A.

Thus, the collection manifold 8 and the distribution-side connection block 72A can be fastened by the fixing portion 88 after adjusting the arrangement of the collection manifold 8A and the distribution-side connection block 72A. Further, the distribution manifold 7A and the collection-side connection block 82A can be fastened by the fixing portion 78 after adjusting the arrangement of the distribution manifold 7A and the collection-side connection block 82A. This makes it easy to adjust the relative arrangement of the distribution manifold 7A, the distribution-side connection block 72A, the collection manifold 8A, and the collection-side connection block 82A.

Further, the side surface of the flange 86 of the collection manifold 8 on one side in the third direction (the side surface on the positive side in the X-axis direction) can abut against the facing surface of the recess 90 provided on the distribution-side connection block 72A. Positioning in the third direction (X-axis direction) can be easily performed by abutting the flange 86 against the recessed portion 90, and workability is improved. Similarly, the side surface of the flange 76 of the distribution manifold 7A on one side in the third direction (the side surface on the positive side in the X-axis direction) can abut against the facing surface of the recess provided in the collection-side connection block 82A. Positioning in the third direction (X-axis direction) can be easily performed by abutting the flange 76 against the recess, and workability is improved.

When the distribution manifold 7A and the collection manifold 8A are held together, since the collection manifold 8A moves to one side in the third direction (the positive side in the X-axis direction), positioning with the surface of the flanges 76, 86 on one side in the third direction (the surface on the positive side in the X-axis direction) is more excellent in workability than positioning with the surface of the flanges 76, 86 on the other side in the third direction (the surface on the negative side in the X-axis direction).

Only a part of the flange 76 is in contact with the distribution manifold 7A and the collection-side connection block 82A. Only a part of the flange 86 is in contact with the collection manifold 8A and the distribution-side connection block 72A. By limiting the contact area to a part of the flanges 76, 86, heat exchange between the distribution manifold 7A and the collection-side connection block 82A and between the collection manifold 8A and the distribution-side connection block 72A can be suppressed.

As a result, the temperature rise of the cold refrigerant flowing through the distribution manifold 7A and the distribution-side connection block 72A can be suppressed, and thus a decrease in the cooling performance of the cooling module 2 can be suppressed. Further, a heat insulation member may be provided between the flange 76 of the distribution manifold 7A and the collection-side connection block 82A, and between the flange 86 of the collection manifold 8A and the distribution-side connection block 72A, and in this case, heat transfer can be further suppressed.

The position at which the flanges 76, 86 is provided is an example, and the position of the flanges 76, 86 can be changed. FIG. 12 is an explanatory top view of a connection portion between a collection-side connection block 82B and a distribution manifold 7A according to a second modification of the example embodiment.

When the flange 86 of the collection manifold 8A is disposed on one side in the second direction (positive side in the Z-axis direction) of the distribution-side connection block 72A, the flange 76 of the distribution manifold 7A may be disposed at the position illustrated in FIG. 12. To be more specific, the flange 76 of the distribution manifold 7A may be disposed on one side in the second direction (the positive side in the Z-axis direction) of the collection-side connection block 82B.

That is, both the flange 76 of the distribution manifold 7A and the flange 86 of the collection manifold 8A may be disposed on the upper surface on one side in the second direction (the positive side in the Z-axis direction). In this case, as illustrated in FIG. 12, the flange 76 of the distribution manifold 7A and the collection-side connection block 82B are fixed by the fixing portion 78 from one side in the second direction (the positive side in the Z-axis direction).

As a result, when the distribution manifold 7A and the collection manifold 8A are assembled, they can be fastened by the fixing portions 78, 88 inserted from one side in the second direction (the positive side in the Z-axis direction), so that the fixing portions 78, 88 can be easily attached and detached during the assembling work.

To be specific, when the distribution manifold 7A and the collection manifold 8A are attached to an actual machine (for example, the heat source 10), the surface on one side in the second direction (the positive side in the Z-axis direction) is the upper side, and the surface on the other side is the lower side. Therefore, the fixing portions 78, 88 can be easily loosened when the positions of the distribution manifold 7A and the collection manifold 8A are shifted for adjustment even after the fuel cell stack is disposed in an actual machine.

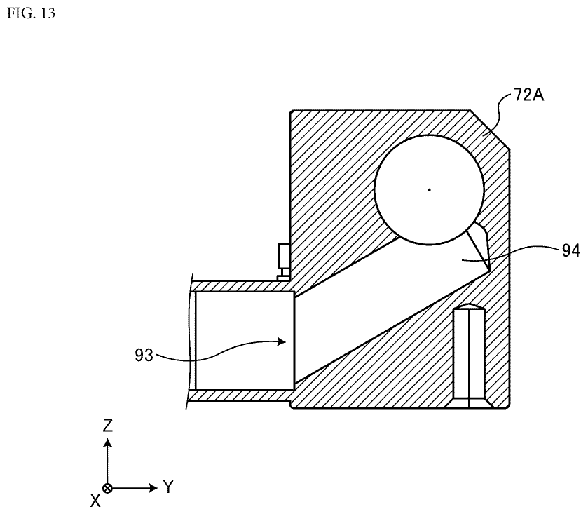

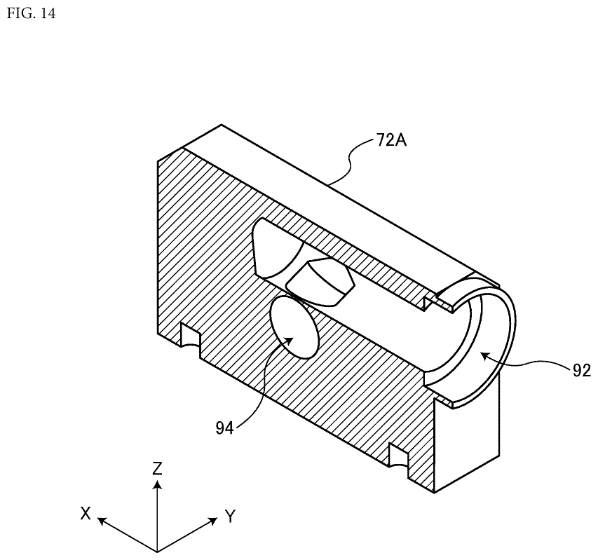

Next, the internal structure of the distribution-side connection block 72A will be described with reference to FIGS. 13 and 14. FIGS. 13 and 14 are explanatory cross-sectional views of the distribution-side connection block 72A. Since the internal structure of the collection-side connection block 82A is the same as the internal structure of the distribution-side connection block 72A, the distribution-side connection block 72A will be described here, and redundant description of the collection-side connection block 82A will be omitted.

As illustrated in FIG. 14, the distribution-side connection block 72A includes a refrigerant inflow port 92 on the other side in the third direction (the negative side in the X-axis direction), and as illustrated in FIG. 13, includes a refrigerant outflow port 93 on the other side in the first direction (the negative side in the Y-axis direction). The flow path extending from the inflow port 92 extends to one side in the third direction (the positive side in the X-axis direction). The flow path extending to one side in the third direction (the positive side in the X-axis direction) is connected to the connection flow path 94 inclined toward the other side in the second direction (the negative side in the Z-axis direction) as it goes toward the other side in the first direction (the negative side in the Y-axis direction), and is connected to the outflow port 93.

The refrigerant flowing into the distribution-side connection block 72A flows in from the inflow port 92, then flows toward one side in the third direction (the positive side in the X-axis direction), flows toward the other side in the first direction (the negative side in the Y-axis direction) by the connection flow path 94, and flows out from the outflow port 93 to the distribution manifold 7A.

With the structure in which the connection flow path 94 is inclined, the flow path can be easily formed by the single distribution-side connection block 72A even in the configuration in which the positions of the inflow port 92 and the outflow port 93 in the second direction (Z-axis direction) are shifted from each other. In addition, the area required for the connection flow path 94 can be reduced, and a screw hole or the like can be provided in the distribution-side connection block 72A.

In the above-described example embodiment, the case where the distribution manifolds 7, 7A, and the flange 76 are separate bodies and the collection manifolds 8, 8A, and the flange 86 are separate bodies has been described, but this is an example. The distribution manifolds 7, 7A, and the flange 76 may be integrated, and the collection manifolds 8, 8A, and the flange 86 may be integrated.

The distribution manifolds 7, 7A, and the collection manifolds 8, 8A may each be formed by full cutting, or may each be composed of a box portion and a lid portion. In this case, a refrigerant flow path is formed inside the box portion. A connection ports 73, 83 are formed in the lid portion. The box portion and the lid portion are joined to each other by welding or brazing.

Note that the present technology can have configurations such as the following.

(1)

A cooling module including: a manifold including: a distribution manifold including a connection port of each of a plurality of joints connected to an inflow port of a refrigerant in a plurality of cooling units; and a collection manifold including a connection port of each of a plurality of joints connected to an outflow port of the refrigerant in the plurality of cooling units, wherein the distribution manifold and the collection manifold are fixed to each other by a fixing portion.

(2)

The cooling module according to (1), wherein the distribution manifold is fixed to the collection manifold by the fixing portion at an end portion on one side in a first direction in which a plurality of the connection ports are arranged, and the collection manifold is fixed to the distribution manifold by the fixing portion at an end portion on another side in the first direction.

(3)

The cooling module according to (2), wherein the distribution manifold includes a connection portion at an end portion on the one side in the first direction, the connection portion opposing, in the first direction, an end portion of the collection manifold on the one side in the first direction, the collection manifold includes a connection portion at an end portion on the other side in the first direction, the connection portion opposing, in the first direction, an end portion of the distribution manifold on the other side in the first direction, the distribution manifold includes a flange extending from an end portion on the other side in the first direction to a position overlapping the connection portion of the collection manifold in a second direction orthogonal or substantially orthogonal to the first direction, and is fixed to the collection manifold by the fixing portion inserted into a hole portion of the flange from one side in the second direction, and the collection manifold includes a flange extending from one end portion on the one side in the first direction to a position overlapping the connection portion of the distribution manifold in the second direction, and is fixed to the distribution manifold by the fixing portion inserted into a hole portion of the flange from the one side in the second direction.

(4)

The cooling module according to (3), wherein the flange of the collection manifold is located on the one side of the connection portion of the distribution manifold in the second direction, and the flange of the distribution manifold is located on the other side of the connection portion of the collection manifold in the second direction.

(5)

The cooling module according to (3) or (4), wherein each of the distribution manifold and the collection manifold includes the connection port on a surface on the one side in the second direction, and the connection port of the distribution manifold and the connection port of the collection manifold are located at positions which do not overlap each other in a third direction orthogonal or substantially orthogonal to the first direction and the second direction.

(6)

The cooling module according to any one of (1) to (5), wherein the distribution manifold and the collection manifold are fixed to each other in a spaced apart relationship.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling module comprising:
a manifold including:
a distribution manifold including a connection port of each of a plurality of joints connected to an inflow port of a refrigerant in a plurality of cooling units; and
a collection manifold including a connection port of each of a plurality of joints connected to an outflow port of a refrigerant in the plurality of cooling units; wherein the distribution manifold and the collection manifold are fixed to each other by a fixing portion.

2. The cooling module according to claim 1, wherein
the distribution manifold is fixed to the collection manifold by the fixing portion at an end portion on one side in a first direction in which a plurality of the connection ports are arranged; and
the collection manifold is fixed to the distribution manifold by the fixing portion at an end portion on another side in the first direction.

3. The cooling module according to claim 2, wherein
the distribution manifold includes a connection portion at an end portion on the one side in the first direction, the connection portion opposing, in the first direction, an end portion of the collection manifold on the one side in the first direction;
the collection manifold includes a connection portion at an end portion on the other side in the first direction, the connection portion opposing, in the first direction, an end portion of the distribution manifold on the other side in the first direction;
the distribution manifold includes a flange extending from an end portion on the other side in the first direction to a position overlapping the connection portion of the collection manifold in a second direction orthogonal or substantially orthogonal to the first direction, and is fixed to the collection manifold by the fixing portion inserted into a hole portion of the flange from one side in the second direction; and
the collection manifold includes a flange extending from one end portion on the one side in the first direction to a position overlapping the connection portion of the distribution manifold in the second direction, and is fixed to the distribution manifold by the fixing portion inserted into a hole portion of the flange from the one side in the second direction.

4. The cooling module according to claim 3, wherein
the flange of the collection manifold is located on the one side of the connection portion of the distribution manifold in the second direction; and
the flange of the distribution manifold is located on the other side of the connection portion of the collection manifold in the second direction.

5. The cooling module according to claim 3, wherein
each of the distribution manifold and the collection manifold includes the connection port on a surface on the one side in the second direction; and
the connection port of the distribution manifold and the connection port of the collection manifold are located at positions which do not overlap each other in a third direction orthogonal or substantially orthogonal to the first direction and the second direction.

6. The cooling module according to claim 1, wherein
the distribution manifold and the collection manifold are fixed to each other in a spaced apart relationship.
